(19) United States
(12) Patent Application Publication
(10) Pub. No.: US 2013/0299955 A1
(43) Pub. Date: Nov. 14, 2013

(54) FILM BASED IC PACKAGING METHOD AND A PACKAGED IC DEVICE

(71) Applicants: Ching Hui Chang, Kaohsiung City (TW); Li Ching Wang, Kaohsiung City (TW); Wen Hung Huang, Kaohsiung City (TW); Pao Tung Pan, Kaohsiung City (TW); Chih Li Huang, Kaohsiung City (TW); I Pin Chen, Kaohsiung City (TW); Chia Han Lin, Kaohsiung City (TW); Chung Hsiung Ho, Kaohsiung City (TW)

(72) Inventors: Ching Hui Chang, Kaohsiung City (TW); Li Ching Wang, Kaohsiung City (TW); Wen Hung Huang, Kaohsiung City (TW); Pao Tung Pan, Kaohsiung City (TW); Chih Li Huang, Kaohsiung City (TW); I Pin Chen, Kaohsiung City (TW); Chia Han Lin, Kaohsiung City (TW); Chung Hsiung Ho, Kaohsiung City (TW)

(73) Assignee: NXP B.V., Eindhoven (NL)

(21) Appl. No.: 13/466,952

(22) Filed: May 8, 2012

(51) Int. Cl. H01L 23/495; H01L 21/50

(52) U.S. Cl. 257/675; 438/113; 257/E21.499; 257/E23.051

(57) ABSTRACT

Film-on-wire (FOW) based IC devices and FOW based methods for IC packaging are described. In an embodiment, a method for packaging an IC dies involves applying a film layer to IC dies and bond wires that are attached to a substrate or a leadframe to form a film-on-wire layer, where the IC dies and the bond wires are enclosed by the film-on-wire layer, and cutting the substrate or the leadframe into IC devices. Other embodiments are also described. The FOW based method for IC packaging can eliminate the need for molding in the IC packaging process and consequently, can reduce the cost of IC packaging and the dimensions of packaged IC devices.

Embodiments of the invention relate generally to electronic circuits and, more particularly, to Integrated Circuit (IC) devices and methods for packaging IC dies.

IC packaging or assembly processes involve enclosing IC chips in protective materials. Conventional molding based IC packaging techniques use a mold tool to form a protective molding around IC chips and bond wires that are attached to the IC chips. The thickness or height of molding based IC devices is controlled by the dimensions of the mold tool. In addition, because molding compounds are typically opaque, it is generally impossible to visually or optically inspect the bond wire connections. Furthermore, because molding compounds generally do not efficiently conduct heat, molding based IC devices are not well suited for use in heat intensive applications.

Film-on-wire (FOW) based IC devices and FOW based methods for IC packaging are described. In an embodiment, a method for packaging IC dies involves applying a film layer to IC dies and bond wires that are attached to a substrate or a leadframe to form a film-on-wire layer, where the IC dies and the bond wires are enclosed by the film-on-wire layer, and cutting the substrate or the leadframe into IC devices. Other embodiments are also described.

The FOW based method for IC packaging can eliminate the need for molding in the IC packaging process. Consequently, expensive and inflexible mold tools are no longer required. Instead, a film layer (e.g., a layer of an adhesive film) is used to form a protective layer that surrounds an IC die and the bond wires. Because the FOW based method for IC packaging eliminates the need for costly and inflexible mold tools, the cost of IC packaging and the dimensions of packaged IC devices can be reduced.

In an embodiment, a method for packaging IC dies involves attaching IC dies onto a substrate or a leadframe, attaching bond wires to the IC dies and to the substrate or the leadframe, applying a film layer to the IC dies and the bond wires to form a film-on-wire layer, where the IC dies and the bond wires are enclosed by the film-on-wire layer, and cutting the substrate or the leadframe into IC devices.

In an embodiment, an IC device includes a substrate or a leadframe having external electrical connectors, an IC die that is attached to the substrate or the leadframe, bond wires that are connected to the IC die and to the substrate or the leadframe, and a film-on-wire layer that encapsulates the IC die and the bond wires.

Other aspects and advantages of embodiments of the present invention will become apparent from the following detailed description, taken in conjunction with the accompanying drawings, depicted by way of example of the principles of the invention.

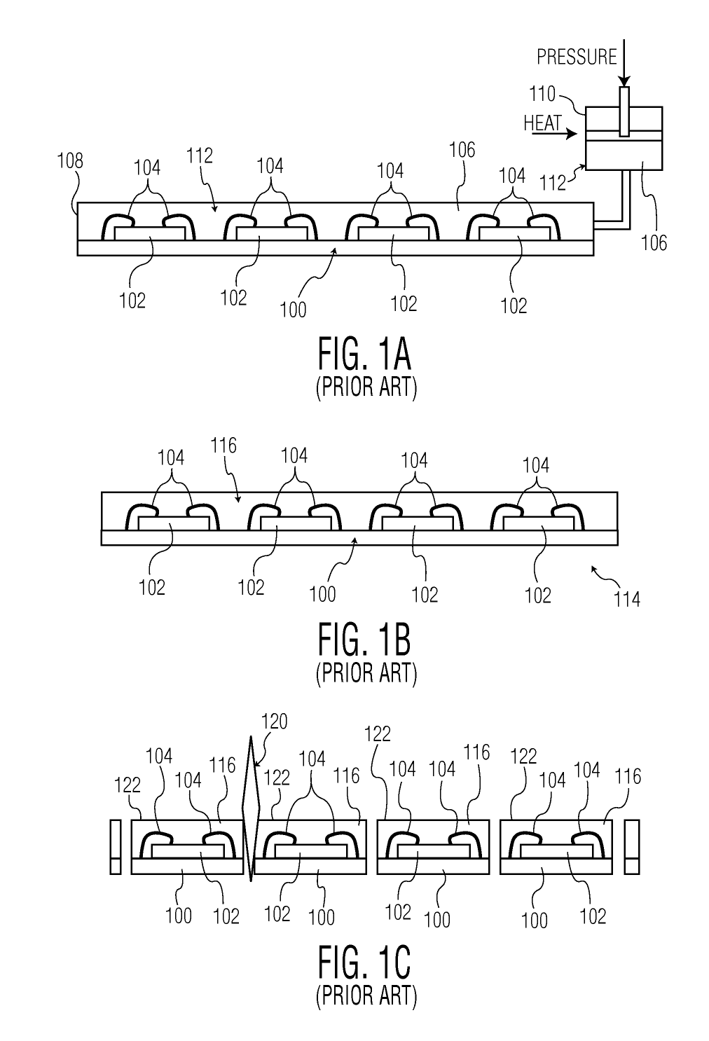

FIG. 1A depicts a molding tool that is used in a conventional IC packaging process.

FIG. 1B is a cross-sectional view of a structure of encapsulated IC chips.

FIG. 1C illustrates an operation in which the structure of FIG. 1B is cut into separate IC devices.

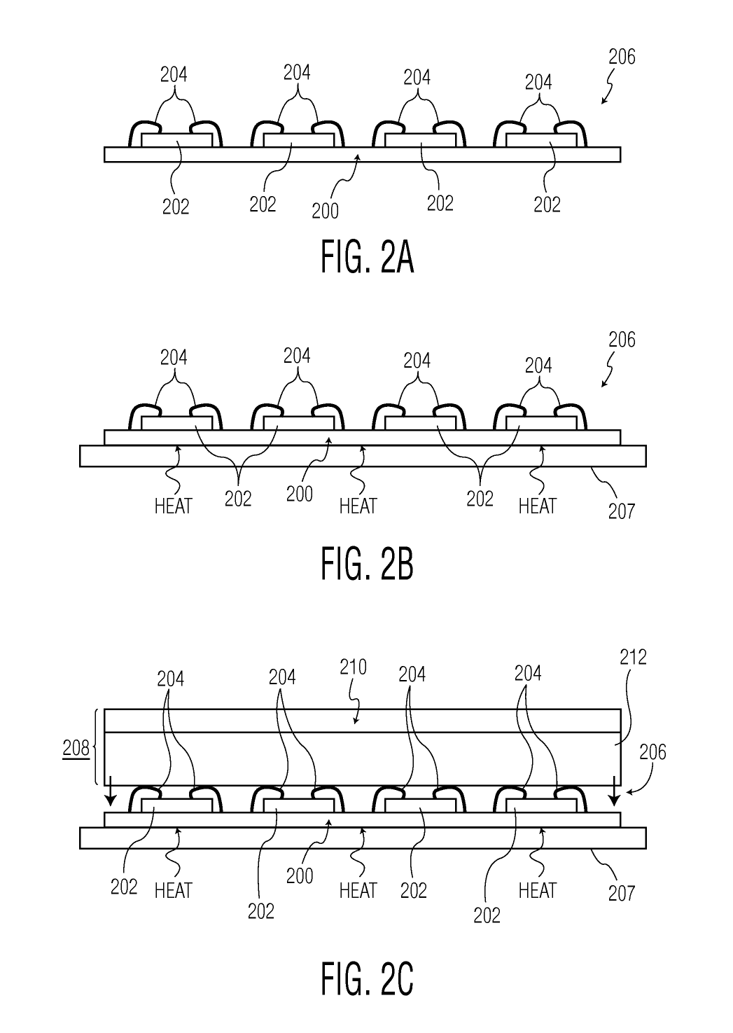

FIG. 2A is a cross-sectional view of a base structure during an IC packaging process in accordance with an embodiment of the invention.

FIG. 2B depicts a preheating operation of the IC packaging process.

FIG. 2C depicts a first step of a film application process in which a film structure is brought into close proximity to the base structure depicted in FIG. 2A.

FIG. 2D depicts a curing step of the film application process.

FIG. 2E is a cross-sectional view of a structure that results from the film application process.

FIG. 2F illustrates an operation in which the structure that results from the film application process is cut into separate IC devices.

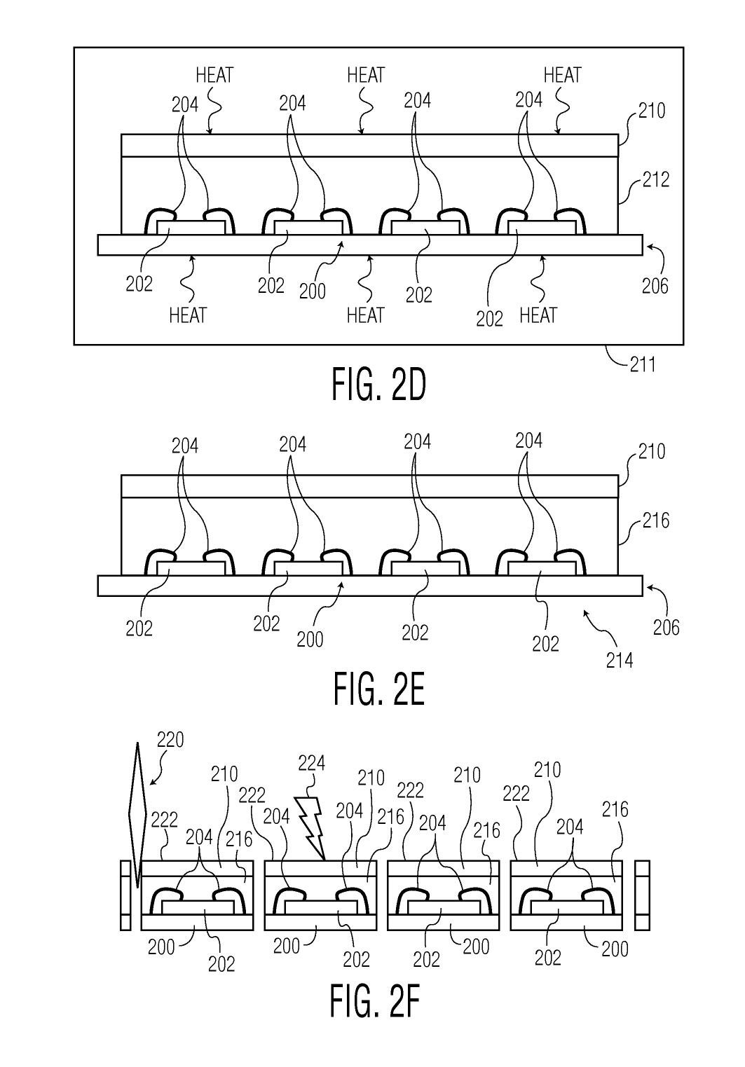

FIG. 3A is a cross-sectional view of a base structure during an IC packaging process in accordance with another embodiment of the invention.

FIG. 3B depicts a preheating operation of the IC packaging process.

FIG. 3C depicts a first step of a film application process in which a film structure is brought into close proximity to the base structure depicted in FIG. 3A.

FIG. 3D depicts a curing step of the film application process.

FIG. 3E is a cross-sectional view of a structure that results from the film application process.

FIG. 3F illustrates an operation the structure that results from the film application process is cut into separate IC devices.

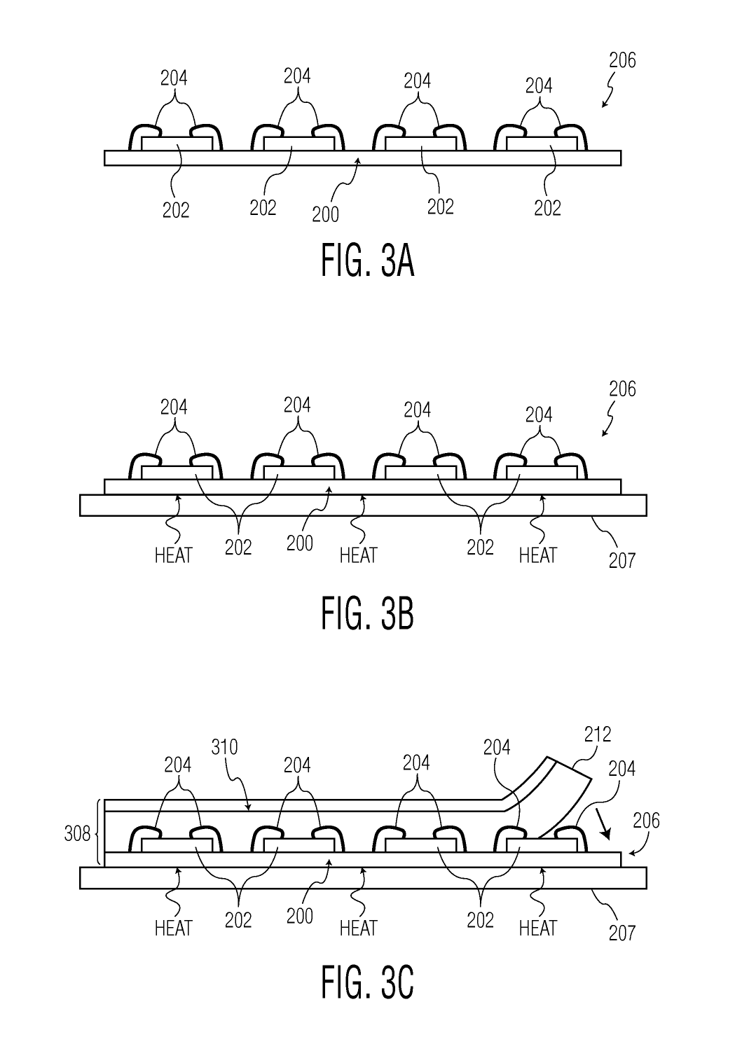

FIG. 4 depicts a Thin and Fine Ball Grid Array (TFBGA) or a Very Thin Profile Fine-Pitch Ball Grid Array (VFBGA) packaged IC device that is packaged using an IC packaging process in accordance with an embodiment of the invention.

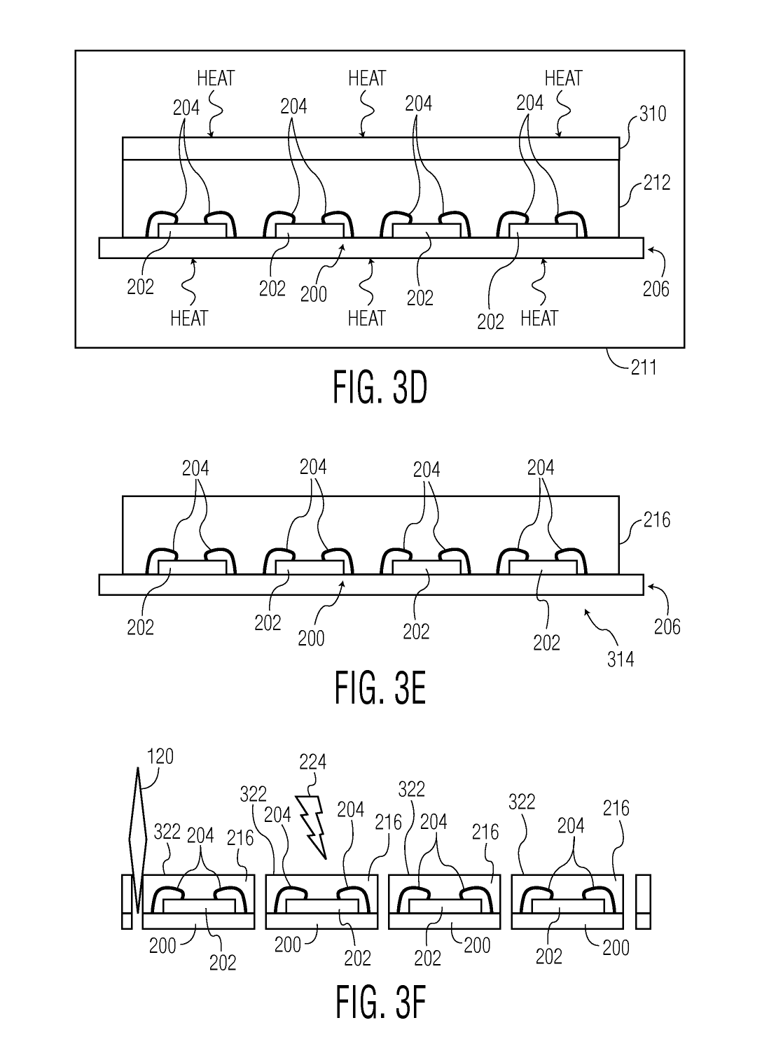

FIG. 5 depicts a High-performance Ball Grid Array (HBGA) or a Land grid array (LGA) packaged IC device that is packaged using an IC packaging process in accordance with an embodiment of the invention.

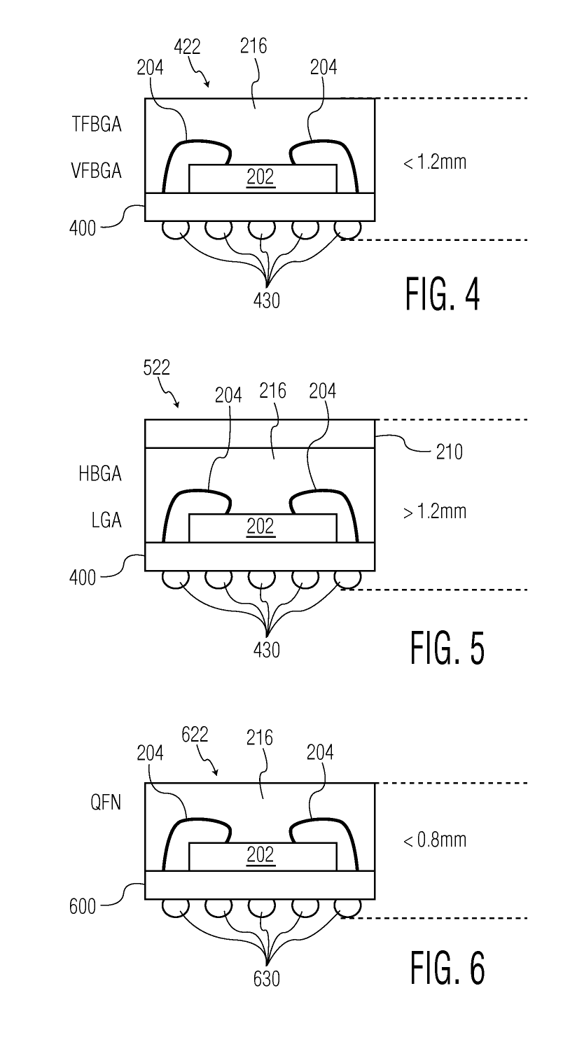

FIG. 6 depicts a Quad-flat no-leads (QFN) package IC device that is packaged using an IC packaging process in accordance with an embodiment of the invention.

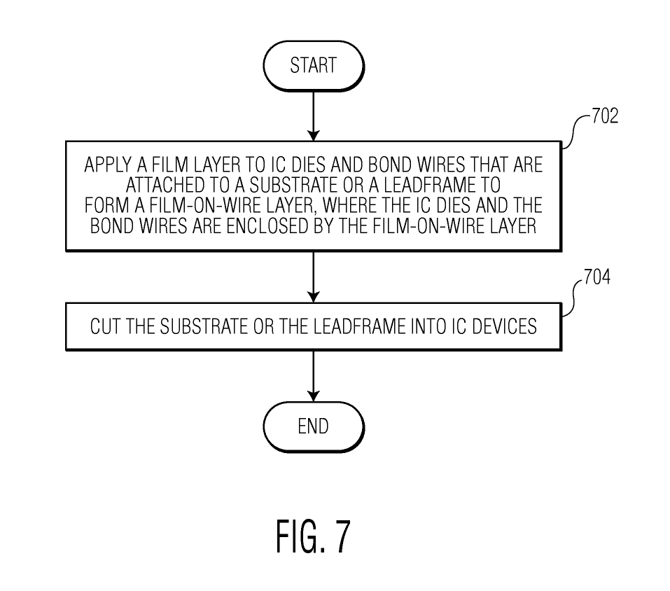

FIG. 7 is a process flow diagram of a method for packaging an IC die in accordance with an embodiment of the invention.

Throughout the description, similar reference numbers may be used to identify similar elements.

It will be readily understood that the components of the embodiments as generally described herein and illustrated in the appended figures could be arranged and designed in a wide variety of different configurations. Thus, the following detailed description of various embodiments, as represented in the figures, is not intended to limit the scope of the present disclosure, but is merely representative of various embodiments. While the various aspects of the embodiments are presented in drawings, the drawings are not necessarily drawn to scale unless specifically indicated.

The described embodiments are to be considered in all respects only as illustrative and not restrictive. The scope of the invention is, therefore, indicated by the appended claims rather than by this detailed description. All changes which come within the meaning and range of equivalency of the claims are to be embraced within their scope.

Reference throughout this specification to features, advantages, or similar language does not imply that all of the features and advantages that may be realized with the present invention should be or are in any single embodiment. Rather, language referring to the features and advantages is understood to mean that a specific feature, advantage, or characteristic described in connection with an embodiment is included in at least one embodiment. Thus, discussions of the features and advantages, and similar language, throughout this specification may, but do not necessarily, refer to the same embodiment.

Furthermore, the described features, advantages, and characteristics of the invention may be combined in any suitable manner in one or more embodiments. One skilled in the relevant art will recognize, in light of the description herein, that the invention can be practiced without one or more of the specific features or advantages of a particular embodiment. In other instances, additional features and advantages may be recognized in certain embodiments that may not be present in all embodiments of the invention.

Reference throughout this specification to “one embodiment,” “an embodiment,” or similar language means that a particular feature, structure, or characteristic described in connection with the indicated embodiment is included in at least one embodiment. Thus, the phrases “in one embodiment,” “in an embodiment,” and similar language throughout this specification may, but do not necessarily, all refer to the same embodiment.

A conventional molding based IC packaging process is described with reference to FIGS. 1A-1C. The conventional molding based IC packaging process uses a mold tool to form a protective molding that encapsulates IC chips and the bond wires that are attached to the IC chips. FIG. 1A depicts a molding tool 106 that is used in a conventional IC molding based packaging process. In the embodiment depicted in FIG. 1, the mold tool includes a mold or a cast 108 and a molding injection unit 110. In a molding operation, the mold is brought in close proximity to IC chips 102 and bond wires 104 that are attached to a substrate 100. Next, the mold is mechanically or magnetically connected to the substrate to form a void space between the mold and the substrate 100, which encloses the IC chips 102 and the bond wires 104. Subsequently, a viscous molding compound 112 is pumped into the void space to form a protective layer over the IC chips 102 and the bond wires 104. In particular, the molding injection unit heats the molding compound, which causes the molding compound to become viscous, and pressurizes the viscous molding compound to force the compound to flow into the mold to fill the void within the mold. If enough molding compound is injected into the void, the void space is completely filled, including all of the space around the IC chips 102 and the bond wires 104.

After being injected into the void space, the heated molding compound is cured and then cooled. The cured molding compound 116 (shown in FIG. 1B) encloses the IC chips 102 and the bond wires 104. In particular, the cured molding compound completely covers the IC chips 102 and the bond wires 104 such that the IC chips 102 and the bond wires 104 are no longer exposed to or accessible from the outside environment. Because multiple IC chips have been enclosed by the cured molding compound on the same substrate, a structure 114 (shown in FIG. 1B) of encapsulated IC chips is generated. FIG. 1B is a cross-sectional view of the structure 114 in which the cured molding compound 116 covers the substrate 100 and forms a protective layer that surrounds the IC chips 102 and the bond wires 104.

FIG. 1C illustrates an operation in which the structure 114 is cut into separate IC devices 122, with each individual unit being referred to as a packaged IC device. In the embodiment illustrated in FIG. 1C, at least one saw blade 120 is used to cut the structure 114 into individual IC devices 122. Each packaged IC device 122 includes a chip 102, bond wires 104 that are connected to the chip 102 and to the substrate 100, the cured molding compound that surrounds the chip 102 and the bond wires 104, and a section of the substrate 100 that is underneath the chip 102 and the bond wires 104.

The conventional molding based IC packaging process illustrated in FIGS. 1A-1C has a number of drawbacks. In particular, the thickness or height of the packaged IC devices 122 is set by the dimensions of the mold tool 106. For example, if a customer orders packaged IC devices of a specific thickness, the IC device manufacturer must ensure that the mold tool can accommodate that particular IC packaging thickness in order to fulfill the customer order. However, because mold tools are expensive, an IC device manufacturer normally only keeps a limited number of mold tools that accommodate the most common IC packaging settings. If IC devices ordered by a customer cannot be made using a mold tool on hand, an IC device manufacturer has to build or rent a new mold tool for that particular customer order. However, building a new mold tool is time consuming and costly. In addition, mold tools are usually not reusable for other customer orders that have different IC packaging dimensions. Renting an appropriate mold tool to fill a customer order is also challenging because of time constraints, costs, and the difficulty of finding the right mold tool for the ordered IC devices. In addition, the overall size of IC circuits that contain finished IC packages is limited by the dimensions of the packaged IC devices. Therefore, the overall size of such circuits is tied to the dimensions of the mold tools.

In addition to the limitation of the thickness or height of the packaged IC devices 222 set by the mold tool 106, conventional molding based IC packaging processes have other drawbacks. For example, because the molding compound 110 is typically opaque, it is generally impossible to visually or optically inspect the connections between the IC chips 102 and the bond wires 104. In particular, the dark color of the molding compound masks the IC chips 102 and the bond wires 104. Consequently, it is impossible for quality control personnel or a machine to visually or optically inspect the connections between the IC chips 102 and the bond wires 104. In addition, molding packaged IC devices are typically prohibited from being used in heat intensive applications because the molding compound 110 usually does not conduct heat well. Consequently, the applications of molding packaged IC devices are unnecessarily limited by the low thermal conductivity of the molding compound. Furthermore, conventional molding based IC packaging processes require the mold tool to be thoroughly cleaned after each use. If the mold tool is not thoroughly cleaned, the quality of subsequently molded packages may be compromised. However, the cleaning of the mold tool requires special knowledge and adds extra costs to the IC packaging process.

Traditionally, film-on-wire techniques are used to vertically stack multiple IC chips. In particular, a thin film layer is positioned between a bottom chip and a top chip and is used to partially cover bond wires that are positioned above an active surface of the bottom chip. A part of the bond wires is covered with the film layer such that the bond wires are prevented from coming in contact with the top chip. Lee et al. (U.S. Pat. No. 6,388,313), St. Amand et al. (U.S. Pat. No. 7,675,180), and Takiar et al. (U.S. Pat. App. Pub. No. 2008/0131998A1) describe some examples of using a film layer to vertically stack multiple IC chips. However, some portion of the bond wires are still exposed to the outside environment and are therefore susceptible to mechanical forces, which could damage the bond wires and/or their connections. Compared to molding compounds, raw film materials are usually more expensive. In addition, because film materials are typically adhesive, film layers can be difficult to handle. Consequently, although a thin film layer can be used to vertically stack multiple IC chips, devices that contain the vertically stacked IC chips are typically packaged with a conventional molding package using an expensive and inflexible mold tool (e.g., the mold tool 106).

Embodiments of the present invention utilize film materials to enclose bond wires and IC chips to form a protective film layer. As previously described, traditional IC chip stacking techniques use a thin film layer to cover parts of the bond wires that are positioned above an active surface of a bottommost chip. However, these techniques do not entirely enclose the bond wires to protect the bond wires. Compared with traditional IC chip stacking techniques, embodiments of the present invention use a film layer to entirely enclose IC chips and the bond wires in packaged IC devices. Compared to molding based IC packaging techniques, embodiments of the present invention can eliminate the need for an expensive and inflexible mold tool in the IC packaging process. Consequently, the cost of IC packaging and the dimensions of packaged IC devices can be reduced. Some embodiments of the present invention will be described in details in FIGS. 2A-3D.

A film based IC packaging process in accordance with an embodiment of the invention is described with reference to FIGS. 2A-2F. In particular, FIG. 2A is a cross-sectional view of a base structure 206 after a first stage of the IC packaging process. In the first stage, IC chips or dies 202 are attached to a substrate or a leadframe 200 and bond wires 204, e.g., gold wires, are used to electrically connect the substrate or leadframe 200 to bond pads (not shown) on the IC dies 202. Although FIG. 2A shows two bond wires 204 connected to each IC die 202, each IC die 202 typically has more than two bond wires 204. In addition, although FIG. 2A does not show any structure that is located underneath the substrate or leadframe 200, some electrical connectors may exist or be subsequently attached underneath the substrate or leadframe 200. Examples of electrical connectors include, without limitation, solder balls, pins, and electrical wires.

In the film based IC packaging process, the substrate or leadframe 200 can be heated before a film structure 208 (shown in FIG. 2C) is applied to the base structure 206. FIG. 2B illustrates a preheating operation of the IC packaging process. In the embodiment depicted in FIG. 2B, the substrate or leadframe 200 is connected (e.g., mechanically or magnetically) to a heating platform 207. Heat is applied to the substrate or leadframe 200 through the heating platform. In an embodiment, the substrate or leadframe 200 is heated to between 100° C. and 130° C. The heating platform may be removed after the preheating of the substrate or leadframe 200.

In an embodiment, the film structure 208 is applied to the base structure 206 to form a protective film after the substrate or leadframe 200 is preheated. An exemplary film application process is described with respect to FIGS. 2C and 2D. FIG. 2C depicts a first step of the film application process in which the film structure 208 is brought into close proximity to the base structure 206. In the embodiment depicted in FIG. 2C, the film structure 208 includes a carrier layer 210 and a film layer 212. The film layer is made of a film material, such as epoxy. In an embodiment, the film layer is an adhesive film, such as a layer of adhesive epoxy, which becomes viscous with heat. In an embodiment, the thickness of the film layer is much smaller (e.g., on the order of one hundredth) than the width and length of the film layer. The film layer is used to form a protective layer over the IC dies 202 and the bond wires 204. In order for the film layer to form the protective layer, the thickness of the film layer should be greater than both the height of the IC dies 202 and the height of the bond wires 204. In an embodiment, the thickness of the film layer is greater than 100 micrometers (μm) while the height of the bond wires 204, which is measured from the surface of the substrate or leadframe 200 to the highest point of the bond wires 204, is around 50 μm.

The carrier layer 210 provides structural (i.e., mechanical) support for the film layer 212 during the film application process. The carrier layer can be made of a wide range of materials. For example, the carrier layer can be a rigid layer, which is made of a material such as glass, plastic, and/or metal, while in another example, the carrier layer can be a flexible layer, which is made of a material such as tape. In an embodiment, the carrier layer is made of a single metal element such as copper or a metal alloy such as an aluminum (Al) alloy. In addition, the carrier layer can serve as a heat sink, which cools packaged IC devices by dissipating heat into the surrounding environment. When used as a heat sink, the carrier layer is made of metal or another material that has a relatively high thermal conductivity. In an embodiment, the carrier layer can be made of a transparent material such as glass or other silicon-like material. A transparent carrier layer makes it possible to visually or optically inspect the connections between the IC dies 202 and the bond wires 204. However, in some embodiments, the carrier layer is made of an opaque material, which gives an FOW packaged IC device an appearance that is similar to the appearance of the molding packaged IC device 122. For example, the carrier layer can be made of dark colored glass such as black glass. In this case, the carrier layer has a color that is similar as the color of the molding compound 110, which masks the IC dies 202 and the bond wires 204 so that it is not possible to visually or optically inspect the bond wire connections. In an embodiment, printing or markings can be printed or burned into the carrier layer.

In the film application process, the film structure 208 is applied to the base structure 206 to form a film-on-wire layer 216 (shown in FIG. 2E) that encloses the IC dies 202 and the bond wires 204. In the first step depicted in FIG. 2C, the film structure 208, which is at room temperature, is brought into close proximity to the base structure 206. In an embodiment, the film structure 208 is brought in close proximity to the base structure 206 by unrolling a film tape over top of the base structure 206 (care is taken not to apply pressure to the bond wires, which could cause damages to the bond wires). Because of the temperature of the heated substrate or leadframe 200, the film layer becomes vicious and gravity causes the film to flow around the IC dies 202 and the bond wires 204 to fill the space around the IC dies 202 and the bond wires 204. After a certain amount of time, the vicious film layer encloses the IC dies 202 and the bond wires 204 such that the IC dies 202 and the bond wires 204 are no longer exposed to the outside environment. The heating of the substrate or leadframe 200 can be performed concurrently with the step of bringing the film structure 208 into close proximity to the base structure 206. In the embodiment depicted in FIG. 2C, the heating platform 207 is attached to the base structure 206 and supplies heat to keep the substrate or leadframe 200 at a temperature that is between 100° C. and 130° C. After the step of bringing the film structure 208 into close proximity to the base structure 206, the heating platform is removed.

Once the IC dies 202 and the bond wires 204 are enclosed in the film, the film is cured to form the film-on-wire layer 216. FIG. 2D depicts a curing step of the film application process in which heat is applied to the carrier layer 210 and the substrate or leadframe 200 to cure the film layer 212. In the embodiment depicted in FIG. 2D, the IC film structure, which includes the carrier layer 210, the film layer 212, and the base structure 206, is baked in an oven 211. In an embodiment, the carrier layer 210 and the substrate or leadframe 200 are exposed to about 160° C. heat for around one hour to cause the film to cure. The cured film is then cooled to, for example, room temperature. After the curing and cooling of the film layer, application of the film-on-wire layer is complete. In an embodiment, the carrier layer is removed after the film-on-wire layer is formed to, for example, make it possible to visually or optically inspect the bond wire connections. Because the film-on-wire layer has been applied to multiple IC dies 202 on the same substrate or leadframe 200, a structure 214 of encapsulated IC dies is generated.

FIG. 2E is a cross-sectional view of the structure 214 that results from the film application process. In the embodiment of FIG. 2E, the film-on-wire layer 216 encapsulates or surrounds the IC dies 202 and the bond wires 204 such that the IC dies 202 and the bond wires 204 are no longer exposed to the outside environment. In an embodiment, the thickness of the film-on-wire layer is greater than 100 μm while the height of the bond wires 204 (measured from the plane of the substrate or leadframe 200) is around 50 μm. Because the thickness of the film-on-wire layer is two times greater than the height of the bond wires 204, the film-on-wire layer can provide structural protection for the IC dies 202 and for the entire length of the bond wires 204.

The structure 214 that results from the film application process can be processed in the same fashion as the structure 114 that results from the conventional molding packaging techniques. Consequently, embodiments of the present invention can re-use cutting tools (e.g., the saw blade 120) that are used in the conventional molding techniques. Therefore, an IC device manufacturer that has invested in the conventional molding techniques does not need to reinvest in new cutting tools in order to adapt to the FOW based IC packaging process of the present invention. FIG. 2F illustrates an operation in which the structure 214 is cut into separate IC devices 222 with each individual unit being referred to as a packaged IC device. In the embodiment depicted in FIG. 2F, at least one saw blade 120 is used to cut the structure 214 into separate packaged IC devices 222. In an embodiment, the packaged IC devices 222 are identical to each other. Each packaged IC device 222 includes an IC die 202, bond wires 204 that are connected to the IC die 202 and to the substrate or leadframe 200, a section of the substrate or leadframe 200 that is underneath the IC die 202 and the bond wires 204, a section of the film-on-wire layer 216 that surrounds the IC die 202 and the bond wires 204, and a section of the carrier layer 210 that is on top of the film-on-wire layer. In an embodiment, laser markings 224 are burned into the packaged IC devices 222. The laser markings can be used to carry a wide range of information including, for example, manufacturer name, part number, serial number, and/or packaging date.

The steps of the process described with reference to FIGS. 2A-2F may be performed by different entities, such as different IC assemblers. For example, a first IC assembler may perform the die attach and wire bonding while a second IC assembler applies the protective film and cuts the substrate or leadframe into separate packaged IC devices.

Compared with traditional molding based IC packaging techniques, embodiments of the present invention can eliminate the need for molding in IC packaging processes. Consequently, inflexible and expensive mold tools are no longer required. If a customer orders packaged IC devices that have a particular thickness from an IC device manufacturer, the IC device manufacturer no longer needs to obtain a mold tool that can produce IC packages with the particular thickness. Because inflexible mold tools are not used, the thickness or height of packaged IC devices is no longer controlled by the dimensions of mold tools. In addition, the overall size of an electrical device that contains an FOW based IC package is not limited by dimensions of the mold tools. Furthermore, because mold tools are no longer required, the cleaning of the mold tools, which demands special knowledge and adds cost to the IC packaging process, is no longer needed. In addition to lifting the limitation on the thickness or height of packaged IC devices, embodiments of the present invention make it possible to visually or optically inspect the connections between IC dies and the bond wires. Additionally, embodiments of the present invention can use a surface material of relatively high thermal conductivity as a heat sink for a packaged IC device, which dispenses heat generated by the packaged IC device to the environment. Consequently, FOW packaged IC devices can be used in heat intensive applications as so called high performance IC devices. Furthermore, compared with molding packaged IC devices, FOW packaged IC devices are relatively easy to post process. For example, laser markings that carry a wide range of information can be burned into FOW packaged IC devices.

An embodiment of an IC packaging process in which the film layer 212 is applied using a flexible carrier layer 310 is described with reference to FIGS. 3A-3F. The initial steps of the IC packaging process depicted in FIGS. 3A-3F are the same as the initial steps of the IC packaging process depicted in FIGS. 2A-2F. In particular, FIG. 3A is a cross-sectional view of a base structure 206 after a first stage of the IC packaging process. In the first packaging stage, the IC dies 202 are attached to the substrate or leadframe 200 and the bond wires 204 are attached to the IC dies 202 and the substrate or leadframe 200.

In the IC packaging process, the substrate or leadframe 200 can be heated before a film structure 308 (shown in FIG. 3C) is applied to the base structure 206. FIG. 3B depicts a preheating operation of the IC packaging process in which heat is applied to the substrate or leadframe 200 through a heating platform 207.

In the IC packaging process, the film structure 308 is applied to the base structure 206 to form a protective film after the substrate or leadframe 200 is heated. An exemplary film application process is described with respect to FIGS. 3C and 3D. FIG. 3C depicts a first step of the application process in which the film structure 308 is brought into close proximity to the base structure 206. In the embodiment depicted in FIG. 3C, a film structure 308 includes the tape-based carrier layer 310 and the film layer 212. The tape-based carrier layer 310 will be later referred to as the tape layer. The tape layer provide structural (i.e., mechanical) support for the film layer during the app process. The tape layer can be removed (e.g., peeled off) in a later stage of IC packaging. In an embodiment, the tape layer can be made of thermo release tape, which loses adhesion in response to the application of heat.

In the film application process, the film structure 308 is applied to the base structure 206 to form a film-on-wire layer 216 (shown in FIG. 3E) that encloses the IC dies 202 and the bond wires 204. In the first step depicted in FIG. 3C, the film structure 308, which is at room temperature, is brought into close proximity to the base structure 206, which included the heated substrate or leadframe 200. In an embodiment, the film structure 308 is brought in close proximity to the base structure 206 by unrolling a film tape over top of the base structure 206. Because of the temperature of the heated substrate or leadframe 200, the film layer becomes vicious and gravity causes the film to flow around the IC dies 202 and the bond wires 204 to fill the space around the IC dies 202 and the bond wires 204. After a certain amount of time, the vicious film layer encloses the IC dies 202 and the bond wires 204 such that the IC dies 202 and the bond wires 204 are no longer exposed to the outside environment. The heating of the substrate or leadframe 200 can be performed concurrently with the step of bringing the film structure 308 into close proximity to the base structure 206. In the embodiment depicted in FIG. 3C, the heating platform 207 is attached to the base structure 206 and supplies heat to keep the substrate or leadframe 200 at a temperature that is between 100° C. and 130° C. After the step of bringing the film structure 308 into close proximity to the base structure 206, the heating platform is removed.

Once the IC dies 202 and the bond wires 204 are enclosed in the film, the film layer is cured to form the film-on-wire layer 216 in a subsequent step in the film application process. FIG. 3D depicts a curing step of the film application process in which heat is applied to the carrier layer 210 and the substrate or leadframe 200 to cure the film layer 212. In the embodiment depicted in FIG. 3D, the IC film structure, which includes the carrier layer 310, the film layer 212, and the base structure 206, is baked in an oven 211. The cured film is then cooled to, for example, room temperature. After the curing and cooling of the film layer, application of the film-on-wire layer is complete. Because the film-on-wire layer has been applied to multiple IC dies 202 on the same substrate or leadframe 300, a structure 314 of encapsulated IC dies is generated. In one embodiment, the tape layer is removed after the film-on-wire layer is formed. For example, the tape layer can be a thermo release tape, which will lose adhesion after being heated for a period of time. Because the film-on-wire layer is typically transparent, the removing of the tape layer makes it possible to visually or optically inspect the connections between the IC dies 202 and the bond wires 204.

FIG. 3E is a cross-sectional view of the structure 314 that results from the film application process. In the embodiment of FIG. 3E, the film-on-wire layer 216 encapsulates or surrounds the IC dies 202 and the bond wires 204 such that the IC dies 202 and the bond wires 204 are no longer exposed to the outside environment. The structure 314 that is generated by the film application process can be processed in the same fashion as the structure 112 that is generated by the conventional molding IC packaging techniques.

FIG. 3F illustrates an operation in which the structure 314 is cut into separate IC devices 322 with each individual unit being referred to as a packaged IC device. In the embodiment depicted in FIG. 3F, at least one saw blade 120 is used to cut the structure 314 into separate IC devices 322. In an embodiment, the packaged IC devices 322 are identical to each other. Each packaged IC device 322 includes an IC die 202, bond wires 204 that are connected to the IC die 202 and to the substrate or leadframe 200, a section of the substrate or leadframe 200 that is underneath the IC die 202 and the bond wires 204, and a section of the film-on-wire layer that surrounds the IC die 202 and the bond wires 204. In an embodiment, laser markings 224 are burned into the packaged IC devices 322.

Because the film-on-wire layer 216 is sufficiently soft and conformable to contain the bond wires 204, the packaged IC device 222 or 322 can be made as a thin film packaged IC device. Depending on the underlying foundation that is used to build a finished IC package, the packaged IC device 222 or 322 can be a substrate type packaged IC device or a leadframe type packaged IC device. Examples of substrate type packaged IC devices include, without limitation, Thin and Fine Ball Grid Array (TFBGA) packaged IC devices, Very Thin Profile Fine-Pitch Ball Grid Array (VFBGA) packaged IC devices, High-performance Ball Grid Array (HBGA) packaged IC devices, or Land grid array (LGA) packaged IC devices. Examples of leadframe type packaged IC devices include, without limitation, Quad-flat no-leads (QFN) packaged IC devices and Small Outline Non-Leaded (SON) packaged IC devices.

The thickness or height of TFBGA and VFBGA packaged IC devices is typically smaller than 1.2 millimeters (mm). FIG. 4 depicts a TFBGA or VFBGA packaged IC device 422 that is packaged using an IC packaging process in accordance with an embodiment of the invention. In the embodiment depicted in FIG. 4, the packaged IC device 422 includes a substrate 400, solder balls 430 that are attached to the substrate 400, an IC chip or die 202 that is attached to the substrate 400, bond wires 204 that are attached to the substrate 400 and the IC die 202, and a film-on-wire layer 216 that is attached to the substrate 400. Although FIG. 4 shows that two bond wires 204 are connected to the IC die 202, in some embodiments, the IC die 202 has more than two bond wires 204. The IC die 202 and the bond wires 204 are enclosed in the film-on-wire layer. The overall thickness or height of the packaged IC device 422, which is measured from the bottom of the solder balls to the top of the film-on-wire layer, is smaller than 1.2 mm.

The thickness or height of HBGA and LGA packaged IC devices is typically larger than 1.2 mm. FIG. 5 depicts an HBGA or LGA packaged IC device 522 that is packaged using an IC packaging process in accordance with an embodiment of the invention. In the embodiment depicted in FIG. 5, the packaged IC device 522 includes a substrate 400, solder balls 430 that are attached to the substrate 400, an IC chip or die 202 that is attached to the substrate 400, bond wires 204 that are attached to the substrate 400 and the IC die 202, a film-on-wire layer 216 that is attached to the substrate 400, and a carrier layer 210 that is attached to the film-on-wire layer. Although FIG. 5 shows that two bond wires 204 are connected to the IC die 202, in some embodiments, the IC die 202 has more than two bond wires 204. The IC die 202 and the bond wires 204 are enclosed in the film-on-wire layer. The overall thickness or height of the packaged IC device 522, which is measured from the bottom of the solder balls to the top of the carrier layer, is larger than 1.2 mm.

The thickness or height of QFN packaged IC devices is typically smaller than 0.8 mm. FIG. 6 depicts a QFN package IC device 622 that is packaged using an IC packaging process in accordance with an embodiment of the invention. In the embodiment depicted in FIG. 6, the packaged IC device 622 includes a leadframe 600, electrical pins 630 that are attached to the leadframe 600, an IC chip or die 202 that is attached to the leadframe 600, bond wires 204 that are attached to the leadframe 600 and the IC die 202, and a film-on-wire layer 216 that is attached to the leadframe 600. Although FIG. 6 shows that two bond wires 204 are connected to the IC die 202, in some embodiments, the IC die 202 has more than two bond wires 204. The IC die 202 and the bond wires 204 are enclosed in the film-on-wire layer. The overall thickness or height of the package IC device 622, which is measured from the bottom of the pins to the top of the film-on-wire layer, is smaller than 0.8 mm.

FIG. 7 is a process flow diagram of a method for packaging IC dies in accordance with an embodiment of the invention. At block 702, a film layer is applied to IC dies and bond wires that are attached to a substrate or a leadframe to form a film-on-wire layer, where the IC dies and the bond wires are enclosed by the film-on-wire layer. At block 704, the substrate or the leadframe is cut into IC devices.

Although the operations of the method herein are shown and described in a particular order, the order of the operations of the method may be altered so that certain operations may be performed in an inverse order or so that certain operations may be performed, at least in part, concurrently with other operations. In another embodiment, instructions or sub-operations of distinct operations may be implemented in an intermittent and/or alternating manner.

In addition, although specific embodiments of the invention that have been described or depicted include several components described or depicted herein, other embodiments of the invention may include fewer or more components to implement less or more feature.

Furthermore, although specific embodiments of the invention have been described and depicted, the invention is not to be limited to the specific forms or arrangements of parts so described and depicted. The scope of the invention is to be defined by the claims appended hereto and their equivalents.

1. A method for packaging Integrated Circuit (IC) dies, the method comprising:
applying a film layer to IC dies and bond wires that are attached to a substrate or a leadframe to form a film-on-wire layer, wherein the IC dies and the bond wires are enclosed by the film-on-wire layer, wherein applying the film layer to the IC dies and the bond wires comprises:
heating the substrate or the leadframe before bringing the film layer in close proximity to the IC dies and the bond wires;
after the substrate or the leadframe is heated, bringing the film layer in close proximity to the heated substrate or the heated leadframe, the IC dies, and the bond wires to cause the film to become viscous and flow around the IC dies and the bond wires to fill the space around the IC dies and the bond wires; and
curing the viscous film layer to form the film-on-wire layer; and
cutting the substrate or the leadframe into IC devices.

2. (canceled)

3. The method of claim 1, wherein applying the film layer to the IC dies and the bond wires comprises applying the film layer to the IC dies and the bond wires using a carrier layer, and wherein the carrier layer is made of metal or glass.

4. The method of claim 3 further comprising removing the carrier layer after the film layer is cured.

5. The method of claim 4, wherein the carrier layer comprises a tape layer.

6. The method of claim 5, wherein the tape layer is made of thermo release tape that loses adhesion in response to the application of heat.

7. The method of claim 1, wherein the film layer comprises a layer of an adhesive film.

8. The method of claim 1, wherein cutting the substrate or the leadframe into the IC devices comprising cutting the substrate or the leadframe into identical IC devices using a saw blade.

9. The method of claim 1 further comprising burning laser markings into the IC devices.

10. The method of claim 1, wherein the IC devices are selected from the group consisting of Thin and Fine Ball Grid Array (TFBGA) packaged IC devices, Very Thin Profile Fine-Pitch Ball Grid Array (VFBGA) packaged IC devices, High-performance Ball Grid Array (HBGA) packaged IC devices, Land grid array (LGA) packaged IC devices, Quad-flat no-leads (QFN) packaged IC devices, and Small Outline Non-Leaded (SON) packaged IC devices.

11. A method for packaging Integrated Circuit (IC) dies, the method comprising:
attaching IC dies onto a substrate or a leadframe;
attaching bond wires to the IC dies and to the substrate or the leadframe;
applying a film layer to the IC dies and the bond wires to form a film-on-wire layer, wherein the IC dies and the bond wires are enclosed by the film-on-wire layer, wherein applying the film layer to the IC dies and the bond wires comprises:
heating the substrate or the leadframe before bringing the film layer in close proximity to the IC dies and the bond wires;
after the substrate or the leadframe is heated, bringing the film layer in close proximity to the heated substrate or the heated leadframe, the IC dies, and the bond wires to cause the film to become viscous and flow around the IC dies and the bond wires to fill the space around the IC dies and the bond wires; and
curing the viscous film layer to form the film-on-wire layer; and
cutting the substrate or the leadframe into IC devices.

12. (canceled)

13. The method of claim 11, wherein applying the film layer to the IC dies and the bond wires comprises applying the film layer to the IC dies and the bond wires using a carrier layer, and wherein the carrier layer is made of metal or glass.

14. The method of claim 13 further comprising removing the carrier layer after the film layer is cured.

15. The method of claim 14, wherein the carrier layer comprises a tape layer that is made of thermo release tape that loses adhesion in response to the application of heat.

16. The method of claim 11, wherein the film layer comprises a layer of an adhesive film.

17. The method of claim 11, wherein cutting the substrate or the leadframe into the IC devices comprising cutting the substrate or the leadframe into identical IC devices using a saw blade.

18. The method of claim 11 further comprising burning laser markings into the IC devices.

19. An Integrated Circuit (IC) device, the IC device comprises:
a substrate or a leadframe having external electrical connectors;
an IC die that is attached to the substrate or the leadframe;
bond wires that are connected to the IC die and to the substrate or the leadframe; and
a film-on-wire layer that encapsulates the IC die and the bond wires.

20. The IC device of claim 19, wherein the IC device further comprises a carrier layer that is attached to the film layer, and wherein the carrier layer is made of metal and is configured to serve as a heat sink.

21. The method of claim 1, wherein heating the substrate or the leadframe comprises applying heat to the substrate or the leadframe through a heating platform that is placed underneath the substrate or the leadframe.

22. The method of claim 11, wherein heating the substrate or the leadframe comprises applying heat to the substrate or the leadframe through a heating platform that is placed underneath the substrate or the leadframe.
